(19) United States
(12) Patent Application Publication
(10) Pub. No.: US 2006/0160317 A1
(43) Pub. Date: Jul. 20, 2006

(54) STRUCTURE AND METHOD TO ENHANCE STRESS IN A CHANNEL OF CMOS DEVICES USING A THIN GATE

(75) Inventors: Huilong Zhu, Poughkeepsie, NY (US); Haining S. Yang, Wappingers Falls, NY (US); Oleg Gluschenkov, Poughkeepsie, NY (US); Dureseti Chidambarrao, Weston, CT (US); Zhijiong Luo, Carmel, NY (US)

Correspondence Address: GREENBLUM & BERNSTEIN, P.L.C., 1950 ROLAND CLARKE PLACE, RESTON, VA, 20191, US

(73) Assignee: INTERNATIONAL BUSINESS MACHINES CORPORATION, ARMONK, NY (US)

(21) Appl. No.: 10/905,710

(22) Filed: Jan. 18, 2005

(51) Int. Cl. H01L 21/8228

(52) U.S. Cl. 438/322

(57) ABSTRACT

A method and structure for producing CMOS devices having thin gates with enhanced stress in a stressed channel is provided. The method allows for producing a CMOS device with a relatively thin gate to provide improved gate response characteristics. Additionally, the structure includes a first stressed film having a raised portion which extends above a top surface of the thin gate. By providing a raised portion of the first stressed film extending about a top surface of the gate, a relatively thick layer of the first stressed film as compared to the thickness of the thin gate is included in the CMOS device and thus allows for higher stress levels in the stressed channel. Additionally, a second stressed film having a stress direction opposite to that of the first stressed film may be included above the thin gate to further enhance the stress in the stressed channel of the CMOS device.

### BACKGROUND OF THE INVENTION

The invention relates to CMOS devices, and more particularly to CMOS devices with stressed channels and thin gates.

Metal-oxide semiconductor transistors generally include a substrate made of a semiconductor material, such as silicon. The transistors typically include a source region, a channel region and a drain region within the substrate. The channel region is located between the source and the drain regions. A gate stack, which usually includes a conductive material, a gate oxide layer and sidewall spacers, is generally provided above the channel region. More particularly, the gate oxide layer is typically provided on the substrate over the channel region, while the gate conductor is usually provided above the gate oxide layer. The sidewall spacers help protect the sidewalls of the gate conductor.

It is known that the amount of current flowing through a channel which has a given electric field across it is generally directly proportional to the mobility of the carriers in the channel. Thus, by increasing the mobility of the carriers in the channel, the operation speed of the transistor can be increased.

It is further known that mechanical stresses within a semiconductor device substrate can modulate device performance by, for example, increasing the mobility of the carriers in the semiconductor device. That is, certain stresses within a semiconductor device are known to enhance semiconductor device characteristics. Thus, to improve the characteristics of a semiconductor device, tensile and/or compressive stresses are created in the channel of the n-type devices (e.g., NFETs) and/or p-type devices (e.g., PFETs). It should be noted that the same stress component, for example tensile stress or compressive stress, improves the device characteristics of one type of device (i.e., n-type device or p-type device) while discriminatively affecting the characteristics of the other type device.

One method of creating stress in the channel of a CMOS device includes forming a film of stressed material over the CMOS device. Thus, some of the stress in the stressed film is coupled to the substrate of the CMOS device thereby generating stress in the channel of the CMOS device. Because the enhanced carrier mobility due to mechanical stress is proportional to the amount of stress, it is desirable to create as much stress in the channel as possible. Additionally, stresses in the stressed film are generated due to appropriately adjusting characteristics in the stressed film deposition process, or introducing stress-producing dopants into the stressed film. It should be noted that such methods of producing a stressed film are limited to producing a stress film with an internal stress on the order of a couple of GigaPascal (GPa). Thus, with the maximum stress of a stressed film being limited to a couple of GPa, it is desirable to develop better methods of coupling the stress in a stressed film into the channel region of a CMOS device to increase the amount of stress in the channel.

When a stress film is deposited over a CMOS device such as by, for example, plasma deposition, the entire device is typically covered SD area and gate. Partial stress in the channel from the stress film is reduced by counter force from the gate stack. On the other hand, the stress in the stress film on the top of the gate can reduce the stress in the channel if the gate stack is thin. However, in some applications thin gates are desirable to reduce gate overlap capacitance between the contact via and the gate to improve device performance. Where such devices require relatively thin gates, stress in the channel is correspondingly reduced. Thus, thin gate CMOS devices typically can not support relatively large stresses in the channel region.

For example, referring to FIG. 1, differences in stress in Dynes/cm² at 2 nm below the gate oxide due to reducing the height of a gate with a conventional liner stress film for a gate length of 60 nm is shown. In FIG. 1, the y-axis represents stress in Dynes/cm² and the x-axis represents distance in microns. As shown in the figure, the stress in the channel region when the gate stack is 150 nm tall is about 450 MegaPascal (MPa). When the gate stack height is reduced to a height of 50 nm, the stress in the channel is reduced to about 250 MPa. When the height of the gate stack is reduced to 30 nm, the stress in the channel is reduced to about 200 MPa. Thus, reduction in gate stack height causes a corresponding reduction in channel stress.

Referring to FIG. 2, in a manner similar to FIG. 1, differences in stress in a channel of a CMOS device as measured to 2 nm below the gate oxide due to reducing the height of the gate stack where the CMOS device has a conventional liner stress film, and the gate width is 30 nm are shown. The y-axis is stress in Dynes/cm² and the x-axis is distance in microns. As the figure shows, the stress in the channel where the gate stack is 150 nm tall is about 470 MPa. When the gate stack height is reduced to 50 nm, the stress in the channel is reduced to about 300 MPa. When the gate stack height is reduced to 30 nm, the stress in the channel is reduced to about 225 MPa. Accordingly, as shown in FIGS. 1 and 2, a reduced gate stack height causes a reduction in stress in the channel of a CMOS device. Such reduction in stress is not preferred because it reduces carrier mobility. Thus, a method is required where a gate stack height can be reduced without reducing the amount of stress in the channel.

As shown in FIGS. 1 and 2, channel stress decreases with decreasing gate height when a traditional stress CA liner method is used to stress the channel of a CMOS device. Although electron and hole mobility can be increased significantly by stress in the channel of CMOS devices, i.e. the higher the stress in the channel, it is difficult to apply a large stress in a channel with known methods, especially as gate stack height decreases. For example, the induced channel stress is only a fraction of the stressing film, for example a nitride film, in magnitude. The most stressful nitride film has a stress of about 1-3 GPa. Hence, the maximum strain effect is limited especially for their gate devices.

### SUMMARY OF THE INVENTION

In a first aspect of the invention, a method of stressing a channel in a CMOS device includes providing a first gate layer of a gate structure on a substrate, and providing a second gate layer of the gate structure on a top surface of the first gate layer. The method also includes providing a first stressed film on a top of the substrate and on a top surface of the second of the gate structure, and removing the second gate layer of the gate structure.

In another aspect of the invention, a method of forming a CMOS device includes providing a gate oxide on a substrate, and providing a first gate layer of a gate structure on the gate oxide. The method also includes providing a second gate layer of the gate structure on the first gate layer of the gate structure, and providing a spacer on top of the substrate and next to sides of the gate oxide, and first and second gate layer of the gate structure. Additionally, the method includes providing a first stressed film over the substrate and the second gate layer of the gate structure, and removing the second gate layer of the gate structure and a portion of the first stressed film.

In another aspect of the invention, a CMOS device includes a gate structure on a substrate, and a first stressed film arranged on the substrate proximate a side of the gate structure, wherein a top surface of the first stressed film is higher than a top surface of the gate structure.

### BRIEF DESCRIPTION OF THE DRAWINGS

FIGS. 1-2 show the effect of reducing the height of a gate on the stress in a channel of a CMOS device;

FIGS. 3-9 show steps of fabricating an embodiment of a CMOS device with a stressed channel in accordance with the invention; and

FIG. 10 shows stress in a channel of an embodiment of a CMOS device in accordance with the invention.

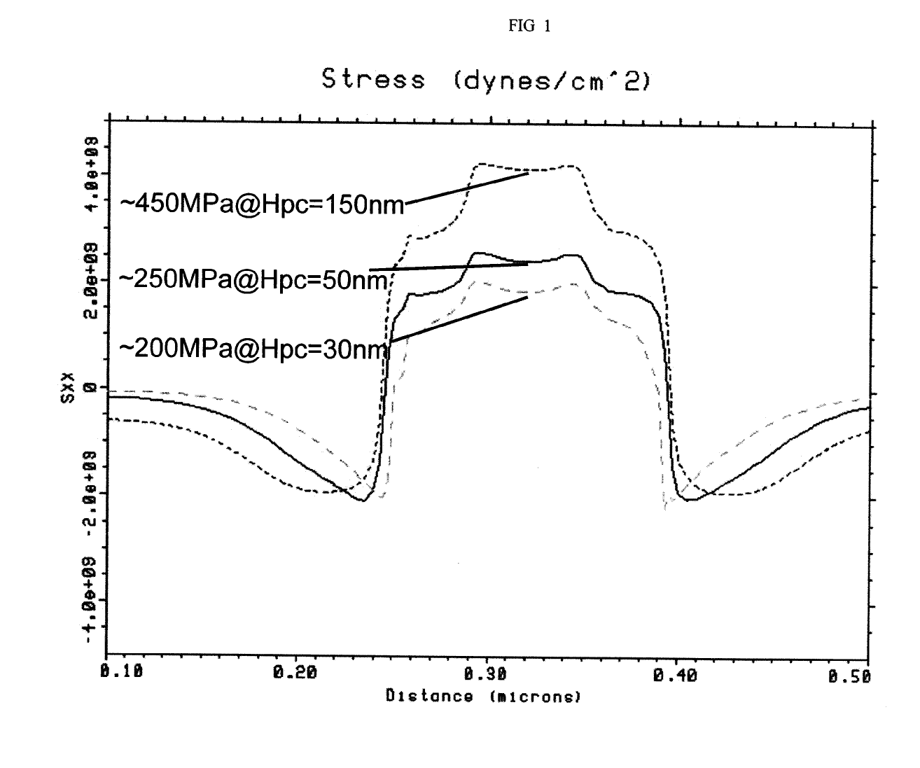

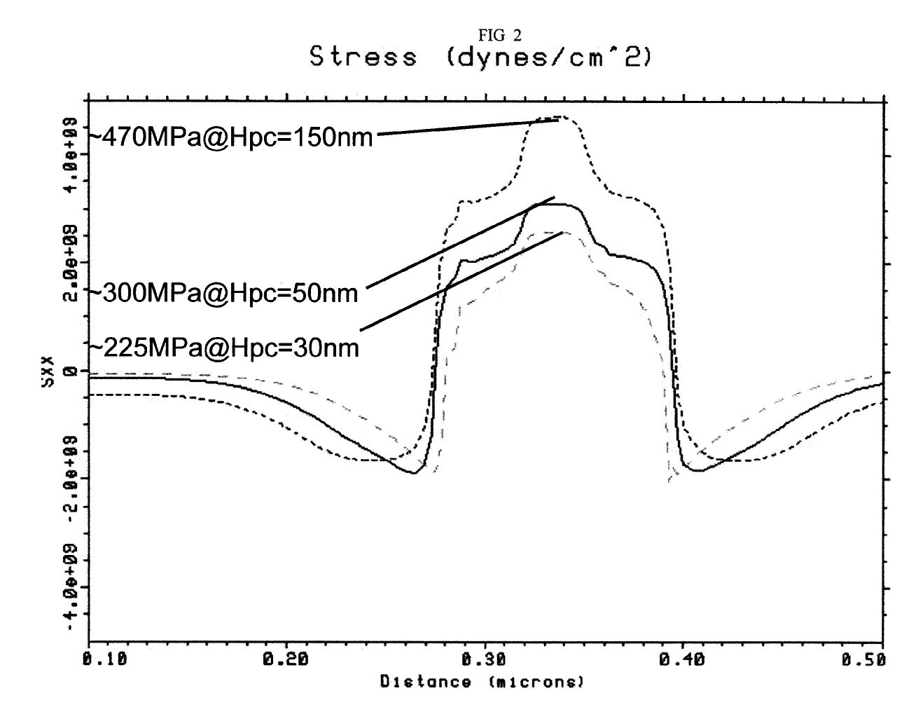

### DETAILED DESCRIPTION OF THE INVENTION

The invention is directed, for example, to enhancing stress in the channel of a CMOS device using a thin gate by forming a taller or 2-layer gate stack or structure, and selectively removing a top part of the gate structure to achieve a thin gate after deposition of a stressed film. Accordingly, a higher stress can be induced in the CMOS channel from the stressed film than would be with a shorter or single gate stock. Additionally, the top parts of CMOS devices so formed can be selectively etched to meet various design criteria. For example, an n-FET gate can be selectively etched to enhance the n-FET performance without degrading p-FET performance if one type of tensile film is deposited on top of the n-FET and p-FET devices. If a dual stressed film with different types of stress, such as for example, a tensile film on an n-FET and a compressive film on a p-FET is used, both n-FET and p-FET gates can be removed to enhance the stress in the respective channel. Thus, the method is compatible with all types of CMOS devices, even when the devices are mixed together on a wafer. Additionally, embodiments also include incorporating at least one such CMOS device into an integrated circuit.

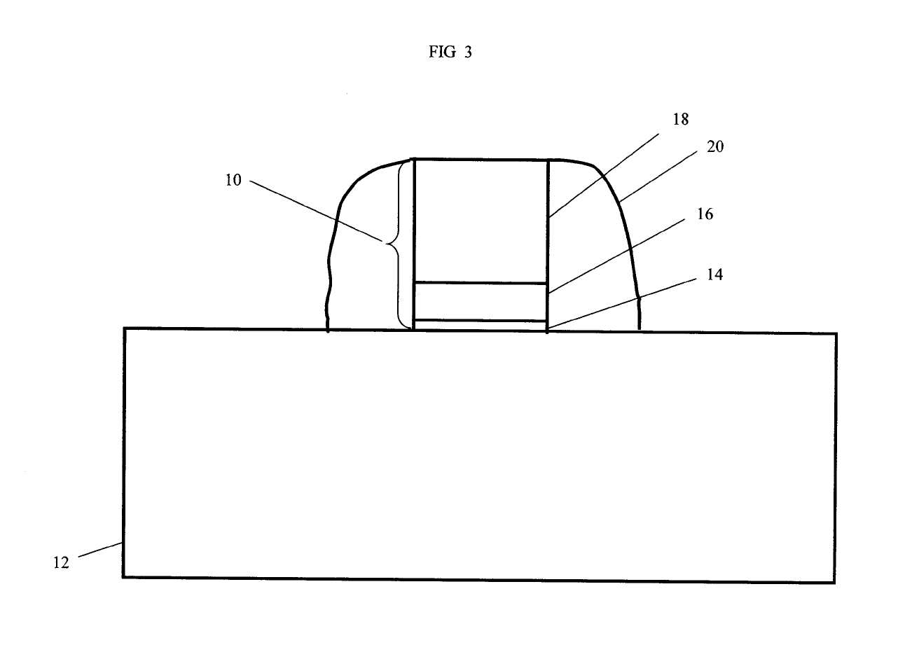

Referring to FIG. 3, a MOSFET device is formed with a poly-SiGe/Si stacked gate structure 10 on a silicon substrate 12. The poly-SiGe/Si stacked gate structure includes a gate oxide 14 deposited on the silicon substrate 12. The gate oxide 14 can be formed on the silicon substrate 12 by any of the methods well-known in the art for forming such a gate oxide such as, for example, thermal oxidation. The gate dielectric can also be formed by deposition of high-K materials such as HfO₂. A first gate layer 16 of the poly-SiGe/Si gate structure is next deposited on the gate oxide 14. The first gate layer 16 of the stacked gate structure 10 may include polysilicon and may be deposited by any of the methods well known in the art for depositing a layer of polysilicon.

On top of the first gate layer 16 of the stacked gate structure 10 is formed a second gate layer 18 of the stacked gate structure 10. The second gate layer 18 of the stacked gate structure 10 may be formed from poly-SiGe, which may be deposited by any of the methods well known in the art for depositing for poly-SiGe on a poly-Si layer using typical stressed film deposition methods, such as, for example, Chemical Vapor Deposition (CVD). Additionally, sidewall spacers 20 are formed on the sides of the stacked gate structure 10. The sidewall spacers 20 may be formed from nitride and deposited by any of the methods well known in the art for making nitride sidewall spacers.

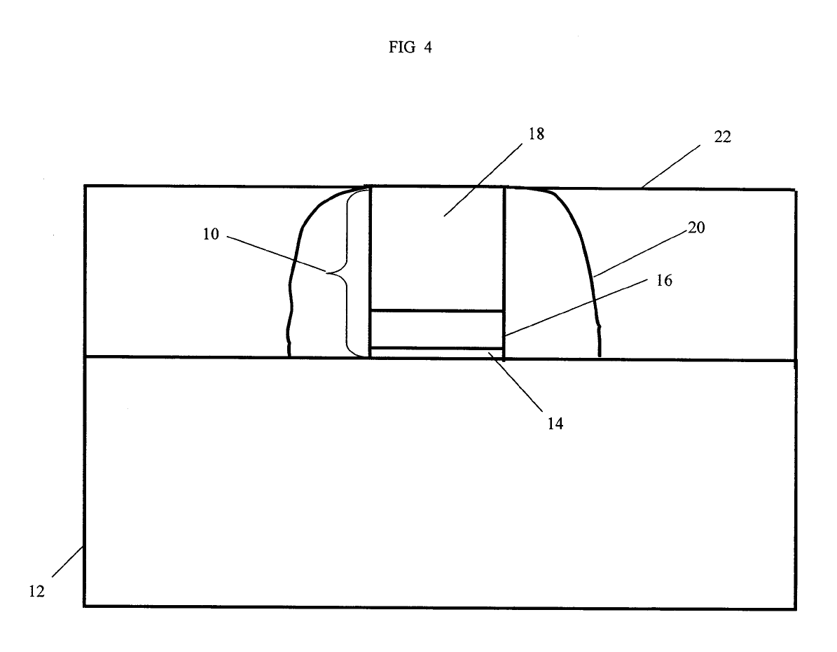

Referring to FIG. 4, a first stressed film 22 is deposited on a top surface of the silicon substrate 12 adjacent the sidewalls 20. Additionally, the first stressed film 22, is deposited on a top surface of the stacked gate structure 10 using typical stressed film deposition methods, such as, for example, PECVD. Accordingly, both the surfaces of the silicon substrate 12, the exposed surfaces of the sidewalls 20 and the top surface of the stacked gate structure 10 are covered with the first stressed film 22. In an application of a n-FET, the first stress film is a tensile stress film. In the application of a p-FET, the first stress film is a compressing stress film. Each of these stress films may be nitride, for example, with the suitably composition adjusted to provide for the proper stress directions and magnitudes.

After the first stressed film 22 is deposited, an upper portion of the first stressed film 22 is removed by, for example, a chemical mechanical planarizing (CMP) process to expose a top surface of the stacked gate structure 10. Thus, a top surface of the first stressed film 22 is substantially level with a top surface of the stacked gate structure 10. In other words, a stressed film 22 is deposited and a cap or top of the stressed film 22 is removed by a CMP process above a top of the gate structure 10.

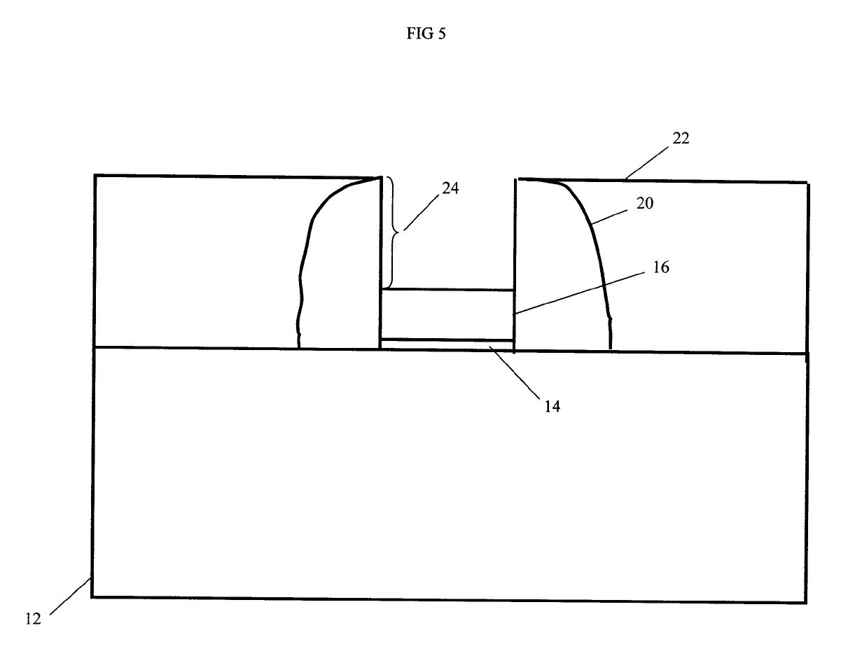

Referring to FIG. 5, after the first stressed film 22 is planarized so that the stacked gate structure 10 has a top surface exposed and substantially level with a top surface of the second gate layer 18, at least a portion of the second gate layer 18 of the stacked gate structure 10 is selectively removed. In this example, because the second gate layer 18 of the stacked gate structure 10 is made from poly-SiGe, it can be removed by etching with, for example, a non-hydrogen containing etch gas mixture.

Accordingly, as shown in FIG. 5, the resulting structure includes a top surface of the first gate layer 16 of the stacked gate structure 10 being exposed with an exposed side of the sidewalls 20 adjacent to and extending above the top surface of the first gate layer 16. Because the second gate layer 18 of the stacked gate structure 10 is selectively removed, the first stressed film 22 remains intact. Consequently, the first stressed film 22, extends above a top surface of the first gate layer 16 of the stacked gate structure 10. The portion of the first stressed film 22, which extends above a top surface of the first gate layer 16 of the stacked gate structure is referred to as a raised portion 24 of the first stressed film 22.

Alternatively, the etching of the second gate layer 18 of the stacked gate structure 10 can be combined with a replacement metal gate process to etch the first gate layer 16 of the stacked gate structure 10 to be replaced with a thin metal gate. After relaxation or removing a top part of the stacked gate structure 10, the area can be refilled with an in-situ doped polysilicon or metal, and etched back to reduce gate overlap capacitance.

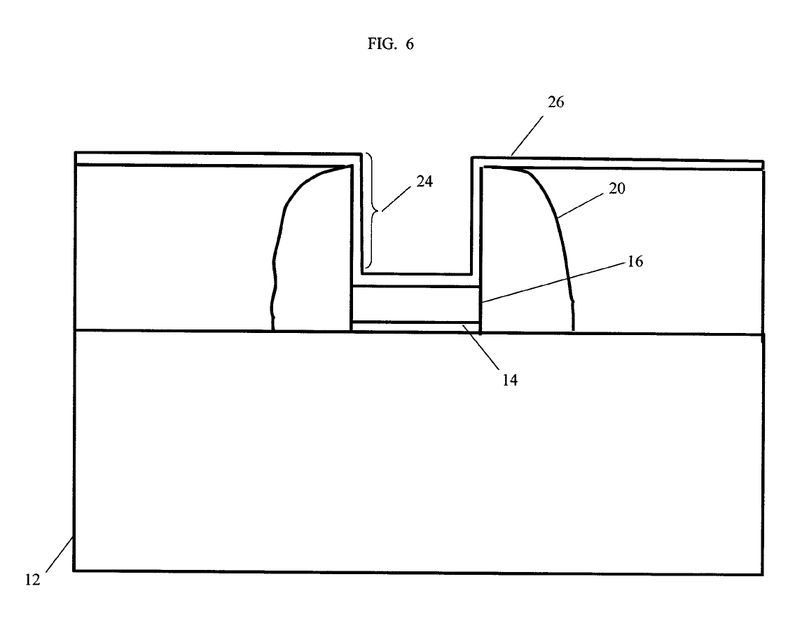

Referring to FIG. 6, a thin layer of metal 26 is deposited on the exposed surfaces of the first stressed film 22, an exposed side of the side wall 20, and a top surface of the first gate layer 16 of the stacked gate structure 10. The thin layer of metal 26 may be deposited by any of the methods well known in the art for depositing thin layers of metal such as, for example, atomic layer deposition (ADL) to a height of, for example 3-10 nm. The thin layer of metal 26 may include nickel, cobalt, titanium, or Pt (Ni, Co or Ti) or other metals with similar properties.

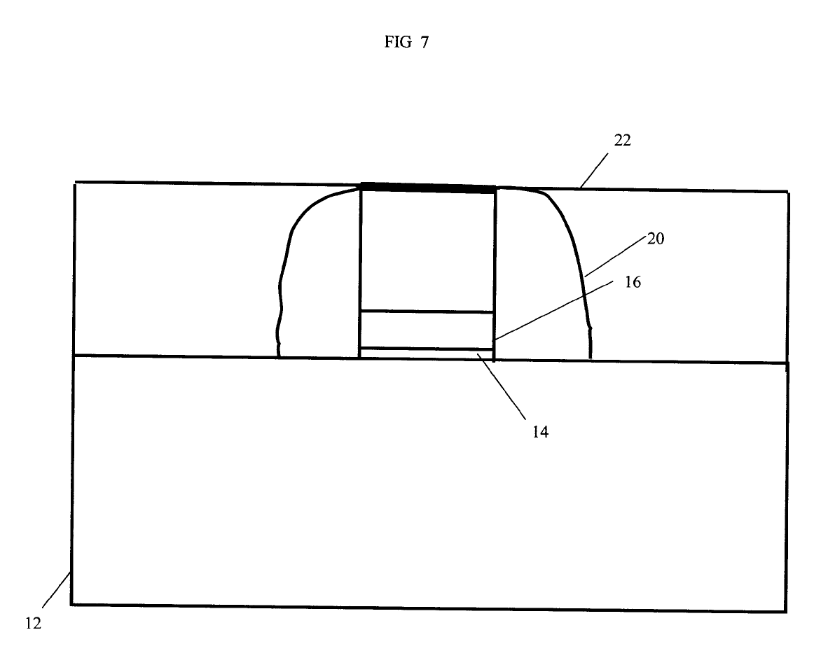

Referring to FIG. 7, an anneal process is performed to create a fully silicided first gate layer 16 of the stacked gate structure 10. The anneal process preferably occurs at 300° to 800° C. for a few seconds to a few minutes depending on temperature and kind of metals. Any residual metal is then removed by an appropriate etching process such as, for example, a wet etch. Accordingly, the first gate layer 16 of the stacked gate structure 10 is converted from a polysilicon to a silicide gate.

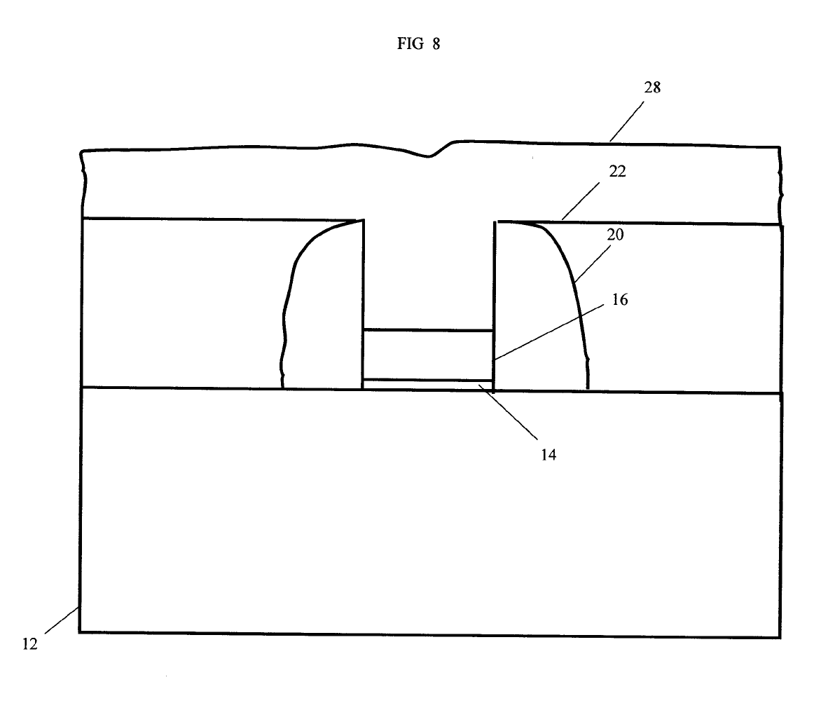

Referring to FIG. 8, a second film 28 is deposited over the first gate layer 16. Accordingly, a top surface of the first stressed film 22, the exposed side of the side wall spacers 20 and a top surface of the silicide gate 16 are covered with the second film 28. Consequently, the second film 28 fills the region formerly occupied above the top surface of the first gate layer 16 formerly occupied by the second gate layer 18.

The second film 28 is deposited to refill a gap or trench above the first gate layer 16, and may be a conductor or an insulator, and additionally it may be a stressed or an unstressed film. Additionally, the second film 28 may be a nitride film with a stress type opposite to the stress direction of stressed film 22. Where the second stressed film 28 has a stress direction opposite to the stress direction of the first stressed film 22, the stress in the channel of the CMOS device will be further enhanced. In the example of an n-FET the second film 28 may be a compressively stressed film; whereas in a p-FET, the second film 28 may be a tensile stressed film.

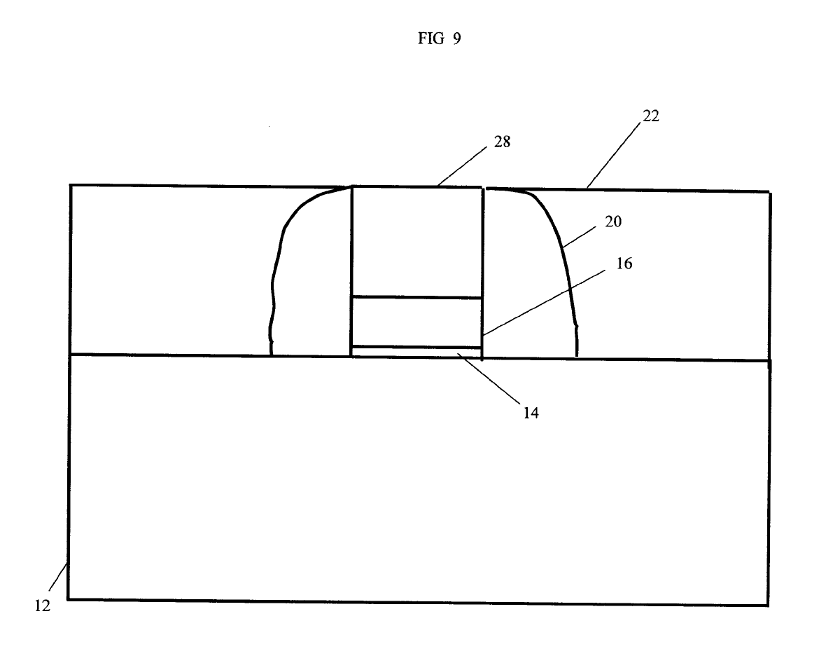

Referring to FIG. 9, an upper portion of the second stressed film 28 is removed by, for example, a CMP process, to expose a top surface of the first stressed film 22. Consequently, a top surface of the first stressed film 22 will extend above a top surface of the first gate layer 16 and will be substantially level with a top surface of the second stressed film 28.

Accordingly, an embodiment of a fabrication process to enhance the stress in the channel of a CMOS device with a thin gate includes creating a raised portion of a stressed film which extends above a top surface of the gate. The raised portion of the first stressed film can be created by forming a gate structure with multiple layers and removing at least one of the layers after the first stressed film has been deposited and planarized to be level with the top of the gate stack structure. In other embodiments, a second stressed film can be deposited in the region formerly occupied by the removed upper layer of the gate stack structure, to further enhance the stress in the channel of the CMOS device with a thin gate.

Referring to FIG. 9, a CMOS device structure with a thin gate having an enhanced stress channel is provided. The CMOS device includes a silicon substrate 12 with a gate dielectric/oxide 14 formed thereon. The CMOS device also includes a thin gate 16. The thin gate 16 may include a metal/silicide gate or a polysilicon gate. On each side of the thin gate 16 and gate oxide 14, and on a top surface of the silicon substrate 12 are sidewall spacers 20. The sidewall spacers 20 may be nitride or oxide or other insulator spacers. Arranged on top of the silicon substrate 12 is a first stressed film 22. The first stressed film 22 is arranged on a side of the sidewall spacers 20.

A top surface of the first stressed film 22 extends above the top surface of the thin gate 16. Consequently, the first stressed film 22 can be substantially thicker than the thin gate 16 and such difference in thickness is the raised portion above the thin gate 16. Because the first stressed film 22 may be relatively thick compared to the thickness of the thin gate 16, the first stressed film 22 can more effectively cause a stress in the channel region of the CMOS device. Thus, the thin gate 16 may be made as thin as required by the circuit application with little or no corresponding reduction in stress of the stressed channel due to decreasing the height of the gate.

In other embodiments, a region above the thin gate 16 and between the side wall spacers 20 may be filled with a second stressed film 28. The second stressed film 28 may be formed having a stress direction which is opposite to the stress direction of the first stressed film 22 thereby further enhancing the stress in the stressed channel of the CMOS device. It should be noted that the above embodiments are equally applicable to n-FET and p-FET devices simply by changing the direction of the stress in the stressing films.

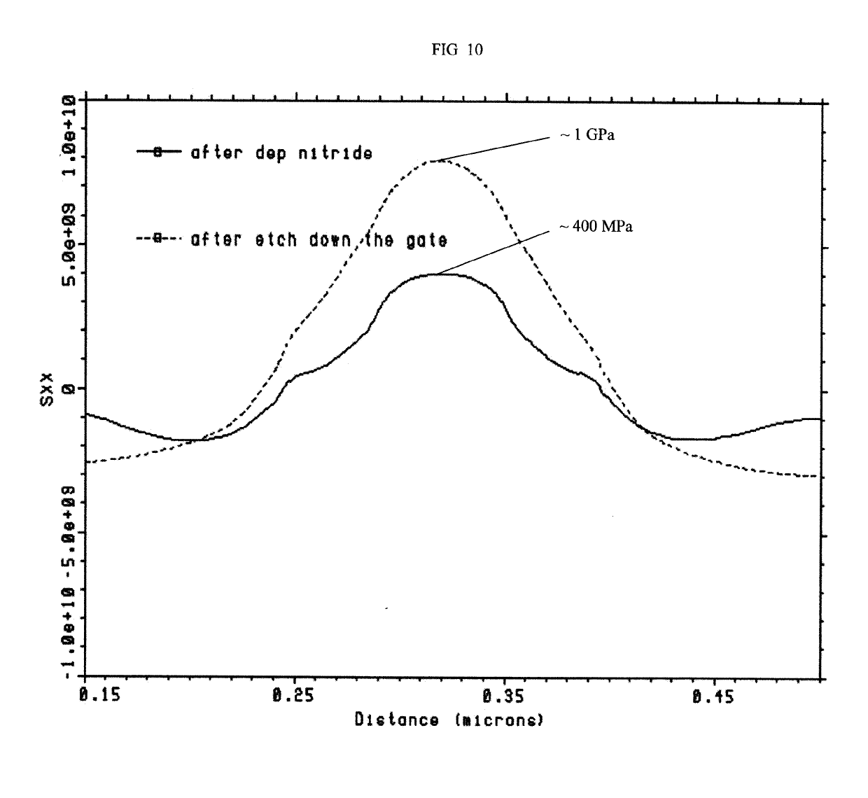

Referring to FIG. 10, a graph showing the improvement of stress in the stress channel for an embodiment of the invention is shown. In the graph, the y-axis is stress in Dynes/cm², and the x-axis is distance through the channel of the CMOS device in microns. The solid line represents stress in the channel after the deposition of the first stressed film. In this example, the first stressed film is a nitride film. As noted, in the figure the stress in the stress channel is about 400 MPa after the stressed film is deposited. The dashed line represents the amount of stress in the stressed channel of the CMOS device after the upper portion of the first stressed film has been removed and the second gate layer of the gate stack structure has been removed to leave the thin gate in place. As shown, removing the upper portion of the first stressed film and the upper portion of the gated stacked structure increases the stress in the stress channel to about 1 GPa.

Accordingly, as shown, by the graph of FIG. 10, deposition of the first stressed film and removal of an upper portion thereof and an upper portion of the gate stack structure results in the stress channel of about 1 GPa. In other words, stress in the stressed channel of the CMOS device increases by about 100 percent after the gate stack structure is etched down to about a thickness of 20 nm, which is the thickness of the thin gate i.e., consequently stress in the channel of devices in accordance with the invention may be about four times larger than that with a conventional liner stress structure.

Thus, embodiments of the invention include CMOS devices where a multi-layered gate structure is formed, a first stressed film is deposited on the top and in the surrounding area of the substrate adjacent to the gate structure and a portion of the first stressed film is removed to expose a top surface of the gate structure. Then, an upper portion of the gate structure is selectively removed while leaving the surrounding portions of the first stressed film intact. Consequently, a CMOS device is formed having a relatively thin gate structure while having a relatively thick stressed film, thereby enhancing the stress in the channel of the CMOS device. Additionally, embodiments of the invention include removing a top portion of the gate structure and replacing the removed portion with a second stressed film where the stress direction in the second stressed film is different than the direction of stress in the first stressed film.

While the invention has been described in terms of exemplary embodiments, those skilled in the art will recognize that the invention can be practiced with modifications and in the spirit and scope of the appended claims.

1-14. (canceled)

15. A CMOS device, comprising;
a gate structure on a substrate,
a first stressed film arranged on the substrate proximate a side of the gate structure, wherein a top surface of the first stressed film is higher than a top surface of the gate structure.

16. The CMOS device of claim 15, wherein a top portion f the gate structure comprises at least one of an in-situ doped polysilicon or a metal.

17. The CMOS device of claim 15, further comprising a second film on the top surface of the first gate layer of the gate structure.

18. The CMOS device of claim 17, wherein the first stressed film stressed in first direction and the second film is either substantially unstressed or is stressed in a second direction.

19. The CMOS device of claim 18, further comprising a suicide layer on a top surface of the first gate layer of the gate structure.

20. The CMOS device of claim 15, further comprising a sidewall on the top surface of the substrate between a side of the first gate layer of the gate structure and the first stressed film, wherein the sidewall is taller than the top surface of the first gate layer of the gate structure
